(19) United States
(12) Patent Application Publication
(10) Pub. No.: US 2025/0212352 A1
(43) Pub. Date: Jun. 26, 2025

(54) OPTICAL MODULE POWER DELIVERY

(71) Applicant: Cisco Technology, Inc., San Jose, CA (US)

(72) Inventors: Steven D. FRIEND, Cupertino, CA (US); Gal KAFTAN, Mountain View, CA (US); Shobhana R. PUNJABI, San Jose, CA (US); Pirooz TOOYSERKANI, Saratoga, CA (US); Qiuhua ZHU, Milpitas, CA (US)

(21) Appl. No.: 18/984,968

(22) Filed: Dec. 17, 2024

Related U.S. Application Data
(60) Provisional application No. 63/613,715, filed on Dec. 21, 2023.

(51) Int. Cl. H05K 7/14; H05K 7/10; H05K 7/20

(52) U.S. Cl. CPC H05K 7/1424; H05K 7/10; H05K 7/1432; H05K 7/20145

(57) ABSTRACT

An apparatus includes a cage defining a plurality of receptacles. Each of the plurality of receptacles is configured to receive a respective pluggable optical module through a front end of the cage. The apparatus further includes a first printed circuit board assembly (PCBA) connected to and extending along a back end of the cage. The first PCBA includes a plurality of connectors. Each of the plurality of connectors is aligned with a respective receptacle of the plurality of receptacles, and is configured to electrically connect with a respective pluggable optical module. The apparatus further includes a second PCBA disposed in parallel with the first PCBA and electrically connected with the first PCBA through a plurality of interconnects, and power circuitry configured to supply power via the second PCBA to the pluggable optical modules.

### CROSS-REFERENCE TO RELATED APPLICATIONS

This application claims benefit of co-pending U.S. provisional patent application Ser. No. 63/613,715 filed Dec. 21, 2023. The aforementioned related patent application is herein incorporated by reference in its entirety.

### TECHNICAL FIELD

Embodiments presented in this disclosure generally relate to network devices, and more specifically, to implementations of circuitry for interfacing with pluggable optical modules.

### BACKGROUND

With the rapid proliferation of networked devices (e.g., the Internet of Things (IoT)), pluggable optical modules have increased in popularity for inter-networking communications due to their high throughput rates. For example, Quad Small Form-factor Pluggable (QSFP) transceiver modules are widely used in state-of-the-art network switches.

Demand for increased communication speeds has resulted in increased power consumption of the pluggable optical modules. For example, the maximum power consumption of a QSFP transceiver module was about 3.5 watts (W) when first introduced in early 2000. Today, a transceiver module having the same form factor can consume about 28 W, presenting a challenge for cooling a network switch having multiple transceiver modules. Power consumption of transceiver modules is expected to further increase in the next few years to 40 W and beyond.

Communication system designs are increasing in port density, bandwidth, and power from one generation to the next. As the number of serializer/deserializer (SerDes) transceivers implemented in an ASIC package reaches a practical (or economical) limit, another approach is to increase the throughput rates of the SerDes transceivers beyond those of a previous generation, e.g., from 100 G PAM4 to 200 G PAM4. However, the increased throughput rates tend to require shorter channel links due to the conductive losses occurring at these higher rates.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates a perspective view of an exemplary network device, according to one or more embodiments.

FIG. 2 illustrates a perspective view of an exemplary pluggable optical module, according to one or more embodiments.

FIG. 3 illustrates a side view of an exemplary circuitry arrangement within a network device, according to one or more embodiments.

FIG. 4 illustrates a rear view of the exemplary circuitry arrangement within a network device, according to one or more embodiments.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is an apparatus that includes a cage defining a plurality of receptacles. Each of the plurality of receptacles is configured to receive a respective pluggable optical module through a front end of the cage. The apparatus further includes a first printed circuit board assembly (PCBA) connected to and extending along a back end of the cage. The first PCBA includes a plurality of connectors. Each of the plurality of connectors is aligned with a respective receptacle of the plurality of receptacles, and is configured to electrically connect with a respective pluggable optical module. The apparatus further includes a second PCBA disposed in parallel with the first PCBA and electrically connected with the first PCBA through a plurality of interconnects, and power circuitry configured to supply power via the second PCBA to the pluggable optical modules.

Another embodiment presented in this disclosure is a network device including an enclosure defining an interior volume, and a cage defining a plurality of receptacles extending into the interior volume. Each of the plurality of receptacles is configured to receive a respective pluggable optical module through a front end of the cage. The network device further includes a first printed circuit board assembly (PCBA) disposed in the interior volume. The first PCBA is connected to and extends along a back end of the cage, and comprises a plurality of connectors. Each of the plurality of connectors is aligned with a respective receptacle of the plurality of receptacles, and is configured to electrically connect with a respective pluggable optical module. The network device further includes a second PCBA disposed in the interior volume. The second PCBA is disposed in parallel with the first PCBA and is electrically connected with the first PCBA through a plurality of interconnects. The network device further includes power circuitry configured to supply power via the second PCBA to the pluggable optical modules.

### Example Embodiments

In current communication system designs, optical modules are plugged in at a front panel and are arranged close to the application-specific integrated circuit (ASIC), and within this configuration the printed circuit board (PCB) routing is reasonably well optimized to minimize channel losses. As a result, it can be challenging to reduce the distances of the PCB routing any further. Other approaches to reduce channel loss involves using a lower-loss PCB material and/or using cabling to bypass the PCB routing, but these approaches tend to introduce other issues such as increased costs, less efficient cooling, airflow blockages, and other design complexities.

In another approach, the ports may be arranged to circumscribe the ASIC, but this requires the optical modules to be plugged in at about 180 degrees to the PCB. This arrangement requires power delivery to the optical modules in a tight space where there is little room for other components such as power circuitry, hot swap circuitry, and so forth. Additionally, any components placed in this area tend to displace the routing needed to support the high-speed signals.

As mentioned above, the power consumption of the optical modules also continues to increase substantially, and is expected to exceed 40 W in subsequent generations. Cooling solutions for the optical modules may require unconventional airflow paths, such as forming vent holes through the PCB.

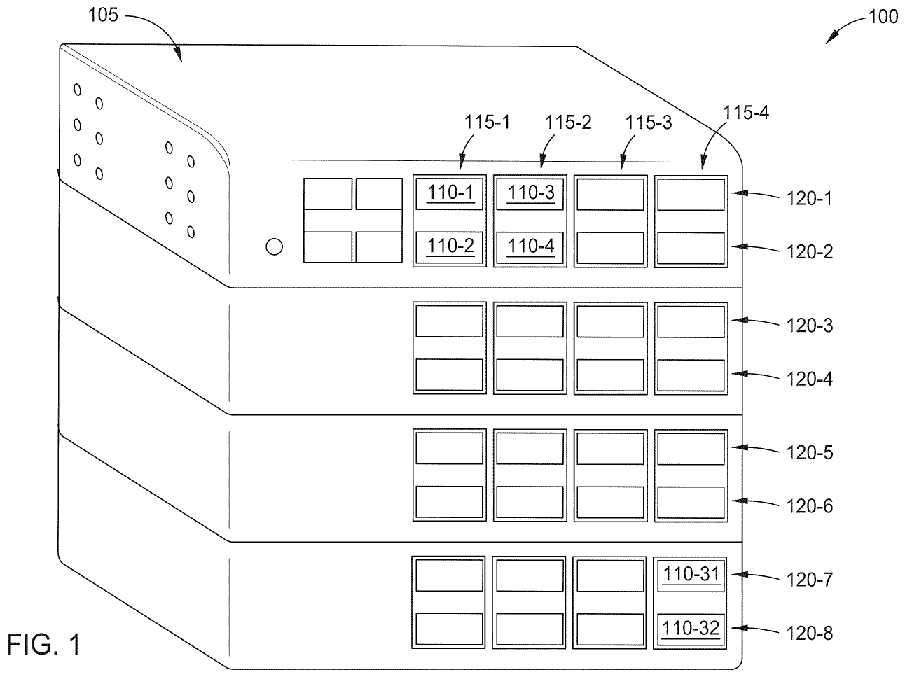

FIG. 1 illustrates a perspective view of an exemplary network device 100, according to one or more embodiments. The network device 100 may be implemented in any suitable form, such as network storage, a server, a switch, a router, a hub, a network interface card (NIC), and so forth. The network device 100 comprises an enclosure 105 that houses a plurality of electrical and/or optical components. The enclosure 105 may be implemented as a standalone device or a rack-mounted device.

The network device 100 comprises a plurality of receptacles 110-1, 110-2, 110-3, 110-4, . . . , 110-31, 110-32 (collectively or generically referred to as receptacle(s) 110) that are disposed within the enclosure 105 and that are externally accessible. Although thirty-two (32) receptacles 110 are shown, other numbers of receptacles 110 are also contemplated.

Each of the receptacles 110 is configured to receive a pluggable optical module (also referred to as an optical module) into an interior volume of the receptacle 110. The receptacles 110 may be dimensioned to receive optical modules having standardized or proprietary form factors. In some embodiments, each optical module comprises a transceiver module providing one or more transmit channels and one or more receive channels using one or more externally-connected optical fibers. The various components of the network device 100 within the enclosure 105 may provide electrical and/or optical connectivity between the different optical modules and/or may provide other functionality. As shown, the plurality of receptacles 110-1, 110-2, 110-3, 110-4, . . . , 110-31, 110-32 are arranged in four (4) columns 115-1, 115-2, 115-3, 115-4 (collectively or generically referred to as column(s) 115) and eight (8) rows 120-1, 120-2, . . . , 120-8 (collectively or generically referred to as row(s) 120). The receptacles 110 are grouped in pairs such that both receptacles 110 of a pair are arranged within a particular column 115, one receptacle 110 of the pair is arranged in a first row 120, and the other receptacle 110 of the pair is arranged in a second row 120. For example, the receptacles 110-1, 110-2 are arranged in column 115-1, the receptacle 110-1 is arranged in row 120-1, and the receptacle 110-2 is arranged in row 120-2.

Although the enclosure 105 is shown with a configuration of four columns 115 and eight rows 120 of the receptacles 110, other configurations having different numbers of the receptacles 110, different numbers of rows 120 and/or columns 115, different groupings of the receptacles 110, non-rectangular matrix arrangements of the receptacles, etc. are also contemplated. Beneficially, according to the embodiments described herein, the enclosure 105 may be implemented with a greater number and/or a denser arrangement of the receptacles 110, as the arrangement of circuitry supports power delivery to the receptacles 110 with adequate cooling.

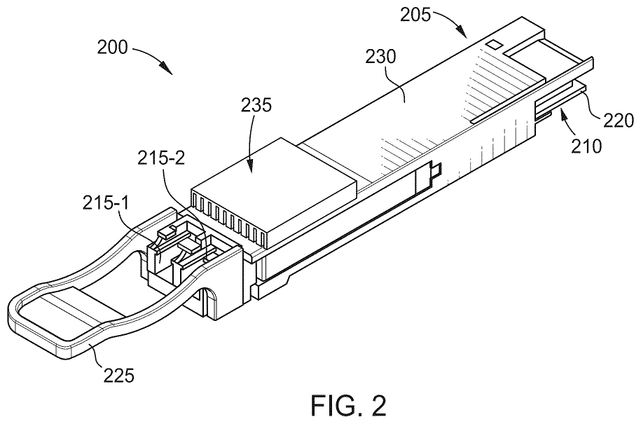

FIG. 2 illustrates a perspective view of an exemplary pluggable optical module 200, according to one or more embodiments. The optical module 200 may be used in conjunction with other embodiments, such as being removably insertable into various receptacles 110 of the network device 100 of FIG. 1.

The optical module 200 comprises a housing 205 that houses electrical components and optical components, at least some of which may be included in a printed circuit board assembly (PCBA) 210 of the optical module 200. One or more external receptacles 215-1, 215-2 are connected to the housing 205, each configured to receive a corresponding optical connector to connect an optical fiber with the optical components in the housing 205. The PCBA 210 defines an edge connector 220 that provides external electrical connections to the electrical components in the housing 205.

In some embodiments, a top surface 230 of the housing 205 provides a thermally conductive interface to remove heat generated by the operation of the electrical components and/or optical components of the optical module 200. In some embodiments, the top surface 230 connects to a heat sink assembly 235, which may be attached to the top surface 230 or to the receptacle 110 (such that the top surface 230 contacts the heat sink assembly 235 when the optical module 200 is received into the receptacle 110). Airflow through the network device 100 is typically established using fans within or near the enclosure 105. In some embodiments, air is drawn into the enclosure 105 through vent openings at a front end of the enclosure, and the airflow passes over the top surface 230 (and past other surfaces or components of the optical module 200) removes heat from the optical module 200.

The optical module 200 further comprises a handle 225 attached to the housing 205. The handle 225 generally assists in the insertion of the optical module 200 into the receptacle 110 and/or removal of the optical module 200 from the receptacle 110.

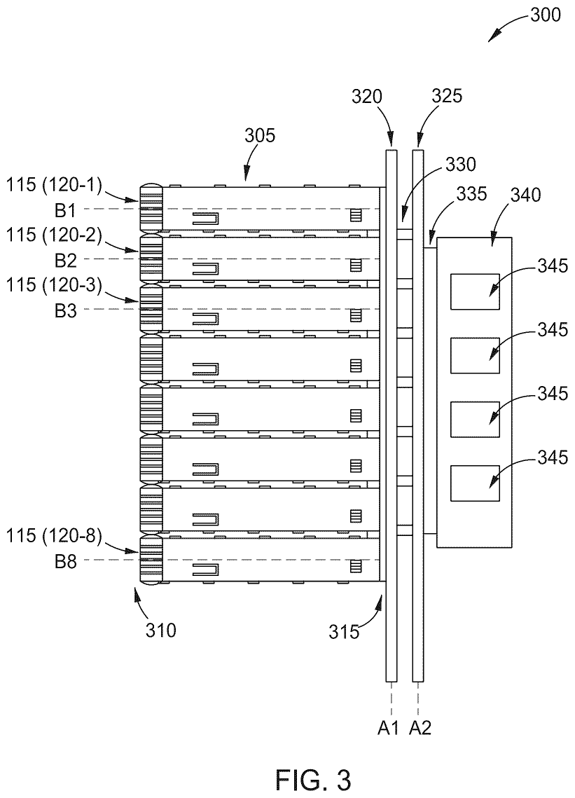

FIG. 3 illustrates a side view of an exemplary circuitry arrangement within a network device, according to one or more embodiments. The features in diagram 300 may be used in conjunction with other embodiments, such as being used in the network device 100 of FIG. 1.

In the diagram 300, a cage 305 defines the plurality of receptacles 115, which as shown are arranged in eight rows 120-1, 120-2, . . . , 120-8. The cage 305 may be constructed of any material(s) capable of supporting a plurality of optical modules 200, such as stainless steel or a copper alloy. Within the cage 305, the plurality of receptacles 115 may be integrally formed as a single structure, or may be attached to each other directly and/or through a common structure (e.g., a frame or base).

Each of the plurality of receptacles 115 is configured to receive a respective optical module 200 through a front end 310 of the cage 305. A first PCBA 320 is connected to, and extends along, a back end 315 of the cage 305. The first PCBA 320 is arranged in a first plane that extends into the page. The first plane is indicated by a first axis A1 included in the first plane. In some embodiments, the plurality of receptacles 115 have longitudinal axes B1, B2, B3, . . . , B8 that are parallel to each other and that are perpendicular to the first plane. In some embodiments, the first PCBA 320 comprises a vertical line card (VLC). A VLC-based implementation tends to provide shorter signal traces (e.g., between about 1 inch and 3 inches) which supports greater transmission speeds at greater densities.

The first PCBA 320 comprises a plurality of connectors (not shown) that are arranged near the back end 315 of the cage 305, and in some cases extend into the interior volume of the plurality of receptacles 115. In some embodiments, each of the plurality of connectors is aligned with a respective receptacle 110 and is configured to electrically connect with a respective optical module 200 when inserted in the receptacle 110. For example, each of the plurality of connectors of the first PCBA 320 may receive an edge connector 220 of the optical module 200. The first PCBA 320 may include processor(s) or other circuitry that is connected with the plurality of connectors, and that provides functionality of the network device 100 and interconnectivity between the optical modules 200.

As discussed above, cooling solutions to effectively dissipate or vent heat become more important as the power consumption of optical modules 200 continues to increase. In some embodiments, the first PCBA 320 includes a plurality of vent openings to allow airflow through the receptacles 115 along the longitudinal axes B1, B2, B3, . . . , B8 and through the first PCBA 320, e.g., exhausting into an interior volume of the enclosure 105 or exhausting out of the enclosure 105.

Minimizing the length of the signal traces on the first PCBA 320 supports greater transmission speeds, but corresponds to a greater density of the circuitry included in the first PCBA 320. Thus, certain functionality of the network device 100 such as power circuitry, hot swap circuitry, filtering circuitry and so forth tends to displace the routing of the signal traces and may also contribute to localized heating near the cage 305.

In some embodiments, a second PCBA 325 is disposed in parallel with the first PCBA 320 and is electrically connected with the first PCBA 320 through a plurality of interconnects 330. The second PCBA 325 is arranged in a second plane that extends into the page. The second plane is indicated by a second axis A2 included in the second plane. In some embodiments, the longitudinal axes B1, B2, B3, . . . , B8 of the plurality of receptacles 115 are perpendicular to the second plane. Although not shown, spacers or other supports may be disposed between the first PCBA 320 and the second PCBA 325 to arrange them in parallel with each other.

The plurality of interconnects 330 may have any suitable implementation. In some embodiments, the plurality of interconnects 330 electrically connect the first PCBA 320 and the second PCBA 325 when arranged in the parallel configuration (e.g., when contacting the spacers). For example, the plurality of interconnects 330 may comprise surface-mount technology (SMT) connectors, such as pins that are received into corresponding sockets when the first PCBA 320 and the second PCBA 325 are in the parallel configuration. In another example, the plurality of interconnects 330 may comprise compliant connectors, such as pogo pins, that contact conductive pads when the first PCBA 320 and the second PCBA 325 are in the parallel configuration.

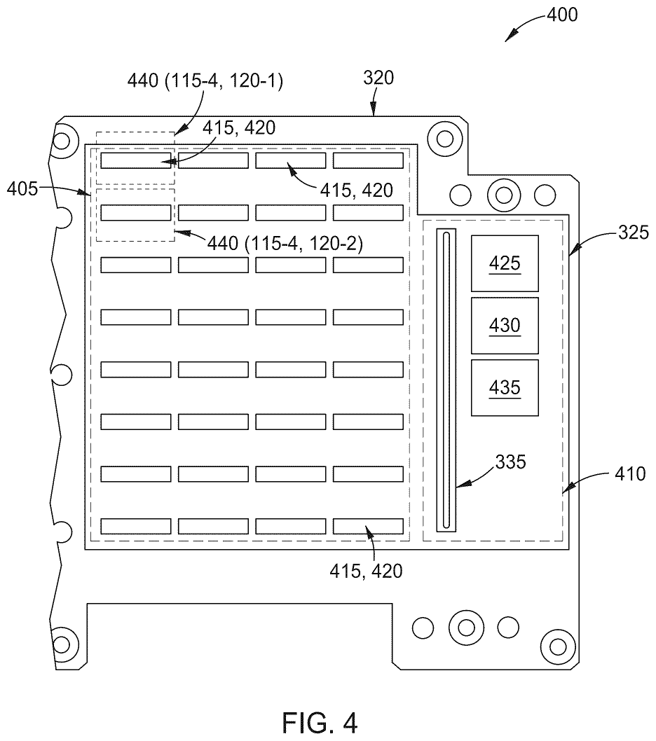

The second PCBA 325 comprises processor(s) or other circuitry that provides functionality of the network device 100. In some embodiments, and referring to FIG. 4, the second PCBA 325 comprises power circuitry 425 that supplies power, via the second PCBA 325, the plurality of interconnects 330, and the first PCBA 320, to the optical modules 200. In some embodiments, the power circuitry comprises a plurality of point-of-load modules, each of which may be implemented as a DC-to-DC converter that is disposed as close as possible to the optical module 200 to provide a stable and regulated output to the optical module 200.

In some embodiments, the second PCBA 325 comprises hot swap circuitry 430 that enables the optical modules 200 to be inserted and/or removed during operation of the network device 100. The hot swap circuitry provides protection and/or sequencing to ensure that terminal constraints (or absolute maximum ratings of electronic components) are not violated during insertion or removal, inrush current is limited to prevent interruption or sag of the supplied power and/or to avoid arcing, and so forth. In some embodiments, the hot swap circuitry may disable a converter of the power circuitry supplying power to a particular optical module 200 prior to disengaging the optical module 200, and/or may hold the converter in a disabled state until all input and output terminations are complete.

In some embodiments, the second PCBA 325 comprises filtering circuitry 435 that provides signal conditioning for the optical modules 200. The filtering circuitry may have any suitable implementation.

By offloading circuitry that provides some of the functionality of the first PCBA 320 to the second PCBA 325, the length of signal traces on the first PCBA 320 may be minimized and/or the amount of heat that is generated near the cage 305 may be reduced.

In some embodiments, the second PCBA 325 comprises at least one additional connector 335, e.g., that receives an edge connector of a removable card 340. In some cases, use of the connector 335 allows circuitry to be less densely arranged and/or further from the cage 305, reducing the amount of heat generated near the cage 305. For example, the removable card 340 may extend in a direction parallel to the longitudinal axes B1, B2, B3, . . . , B8 of the plurality of receptacles 115 to use available clearance within the interior volume of the enclosure 105. In some embodiments, some or all of the power circuitry 425 of the second PCBA 325 is included in the removable card 340. As shown, the removable card 340 comprises a plurality of point-of-load modules 345, which supply power to connectors arranged at ones of the plurality of receptacles 115.

FIG. 4 illustrates a rear view of the exemplary circuitry arrangement within a network device, according to one or more embodiments. The features in diagram 400 may be used in conjunction with other embodiments, such as being used in the network device 100 of FIG. 1.

In the diagram 400, a first region 405 of the second PCBA 325 overlaps with the plurality of receptacles 115, and a second region 410 of the second PCBA 325 is non-overlapping with the plurality of receptacles 115. In some embodiments, the first PCBA 320 defines a first plurality of vent openings 415 that are each aligned with a respective receptacle 110 (shown as an outline 440). Within the first region 405, the second PCBA 325 defines a second plurality of vent openings 420 that are each aligned with a respective vent opening of the first plurality of vent openings 415. In some embodiments, the vent openings 415 of the first PCBA 320 and the vent openings 420 of the second PCBA 325 may be dimensioned based on an amount of airflow needed to cool the optical modules 200. In some embodiments, the vent openings 415 have the same dimensioning as the vent openings 420, although different dimensioning (e.g., different sizes and/or shapes) is also contemplated. Aligning the vent openings 415, 420 provides an improved airflow through the receptacles 115, through the first PCBA 320, and through the second PCBA 325 to remove heat from the optical modules 200 during operation.

In some embodiments, various circuitry of the second PCBA 325 is disposed in the second region 410, which minimizes obstructions to the airflow paths through the receptacles 115 and/or arranging additional heat sources near the airflow paths. As shown, the connector 335 (which may include a removable card 340), as well as the power circuitry 425, the hot swap circuitry 430, and the filtering circuitry 435. Although the power circuitry 425, the hot swap circuitry 430, and the filtering circuitry 435 are shown as separate components, some or all of these may be included in a same processor, ASIC, and so forth.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

The flowchart illustrations and block diagrams in the Figures illustrate the architecture, functionality, and operation of possible implementations of systems, methods, and computer program products according to various embodiments. In this regard, each block in the flowchart illustrations or block diagrams may represent a module, segment, or portion of code, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

In view of the foregoing, the scope of the present disclosure is determined by the claims that follow.

We claim:

1. An apparatus comprising:
a cage defining a plurality of receptacles, each of the plurality of receptacles configured to receive a respective pluggable optical module through a front end of the cage;
a first printed circuit board assembly (PCBA) connected to and extending along a back end of the cage, the first PCBA comprising a plurality of connectors, each of the plurality of connectors aligned with a respective receptacle of the plurality of receptacles, and configured to electrically connect with a respective pluggable optical module;
a second PCBA disposed in parallel with the first PCBA and electrically connected with the first PCBA through a plurality of interconnects; and
power circuitry configured to supply power via the second PCBA to the pluggable optical modules.

2. The apparatus of claim 1,
wherein the first PCBA defines a first plurality of vent openings extending therethrough, each of the first plurality of vent openings aligned with a respective receptacle of the plurality of receptacles.

3. The apparatus of claim 2,
wherein the second PCBA defines a second plurality of vent openings extending therethrough, each of the second plurality of vent openings aligned with a respective vent opening of the first plurality of vent openings.

4. The apparatus of claim 1,
wherein the plurality of receptacles have longitudinal axes that are parallel to each other, and
wherein the first PCBA and the second PCBA are arranged in respective planes that are perpendicular to the longitudinal axes.

5. The apparatus of claim 4, wherein the first PCBA comprises a vertical line card.

6. The apparatus of claim 1, wherein the second PCBA comprises at least one additional connector, wherein the power circuitry is included in a removable card connected to the additional connector.

7. The apparatus of claim 6, wherein the power circuitry comprises a plurality of point-of-load modules.

8. The apparatus of claim 1, wherein the second PCBA comprises the power circuitry.

9. The apparatus of claim 1, wherein the second PCBA comprises hot swap circuitry.

10. The apparatus of claim 1, wherein the second PCBA comprises filtering circuitry.

11. A network device comprising:
an enclosure defining an interior volume;
a cage defining a plurality of receptacles extending into the interior volume, each of the plurality of receptacles configured to receive a respective pluggable optical module through a front end of the cage;
a first printed circuit board assembly (PCBA) disposed in the interior volume, the first PCBA connected to and extending along a back end of the cage, the first PCBA comprising a plurality of connectors, each of the plurality of connectors aligned with a respective receptacle of the plurality of receptacles, and configured to electrically connect with a respective pluggable optical module;
a second PCBA disposed in the interior volume, the second PCBA disposed in parallel with the first PCBA and electrically connected with the first PCBA through a plurality of interconnects; and
power circuitry configured to supply power via the second PCBA to the pluggable optical modules.

12. The network device of claim 11,
wherein the first PCBA defines a first plurality of vent openings extending therethrough, each of the first plurality of vent openings aligned with a respective receptacle of the plurality of receptacles.

13. The network device of claim 12,
wherein the second PCBA defines a second plurality of vent openings extending therethrough, each of the second plurality of vent openings aligned with a respective vent opening of the first plurality of vent openings.

14. The network device of claim 11,
wherein the plurality of receptacles have longitudinal axes that are parallel to each other, and
wherein the first PCBA and the second PCBA are arranged in respective planes that are perpendicular to the longitudinal axes.

15. The network device of claim 11, wherein the second PCBA comprises at least one additional connector, wherein the power circuitry is included in a removable card connected to the additional connector.

16. The network device of claim 15, wherein the power circuitry comprises a plurality of point-of-load modules.

17. The network device of claim 11, wherein the first PCBA comprises a vertical line card.

18. The network device of claim 11, wherein the second PCBA comprises the power circuitry.

19. The network device of claim 11, wherein the second PCBA comprises hot swap circuitry.

20. The network device of claim 11, wherein the second PCBA comprises filtering circuitry.
